(19) United States
(12) Patent Application Publication
(10) Pub. No.: US 2011/0156552 A1
(43) Pub. Date: Jun. 30, 2011

(54) COMPUTER CASE

(75) Inventors: LEI LIU, Shenzhen City (CN); XIAO-ZHU CHEN, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/755,432

(22) Filed: Apr. 7, 2010

(30) Foreign Application Priority Data
Dec. 24, 2009 (CN) 200910312207.1

(51) Int. Cl. H05K 5/02

(52) U.S. Cl. 312/223.2

(57) ABSTRACT

A computer case includes a rear board, and a mounting bracket. An opening is defined in the rear board. The mounting bracket is detachably mounted to the rear board and is able to cover the opening when mounted to the rear board. A plurality of parallel slots is defined abreast of each other in the mounting bracket. The mounting bracket is able to be mounted to the rear board in a first and a second states, the mounting bracket rotates 90 degrees in the second state relative to the first state.

### BACKGROUND

1. Technical Field

The present disclosure relates to a computer case.

2. Description of Related Art

Peripheral component interconnect (PCI) cards are necessarily employed in servers.

In case of a tower server, there is a broad space for receiving elements, such as PCI cards. Therefore, a number of PCI cards can be perpendicularly coupled to a motherboard in a tower server via PCI sockets on the motherboard. These PCI cards are then fixed to a rear board of the case via fasteners, and ports of the PCI cards are exposed through slots defined in the rear board to communicate with peripheral equipment.

However, a case of a rack server is thin and a receiving space in the case is limited, as such, the case of the rack server is neither fit for receiving many PCI sockets nor fit for perpendicularly connected PCI cards coupled with a motherboard in the case. Therefore, a motherboard of a rack server commonly includes only one PCI socket. A riser card is inserted in the PCI socket to perpendicularly couple with the motherboard. A number of PCI cards are perpendicularly coupled to the riser card, and are therefore parallel with the motherboard, so as to fit the limited space.

Because of the different coupling manners for PCI cards, the motherboard of a rack server cannot be used in the tower server.

### BRIEF DESCRIPTION OF THE DRAWINGS

FIG. 1 is an isometric view of an embodiment of a computer case including a rear board and a mounting bracket.

FIG. 2 is an exploded, isometric view of the rear board and the mounting bracket in FIG. 1

FIG. 3 is an assembled, isometric view of the computer case in FIG. 1 and a first motherboard of a tower server.

FIG. 4 is similar to FIG. 1, but the mounting bracket is rotated 90 degrees.

FIG. 5 is an assembled, isometric view of the computer case in FIG. 4 and a second motherboard of a rack server.

### DETAILED DESCRIPTION

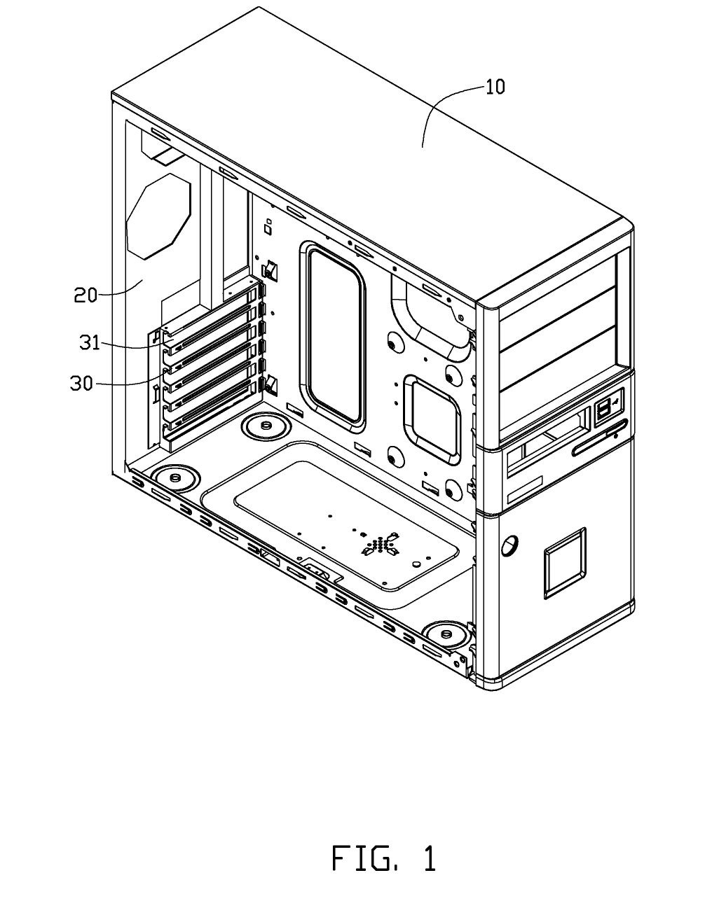

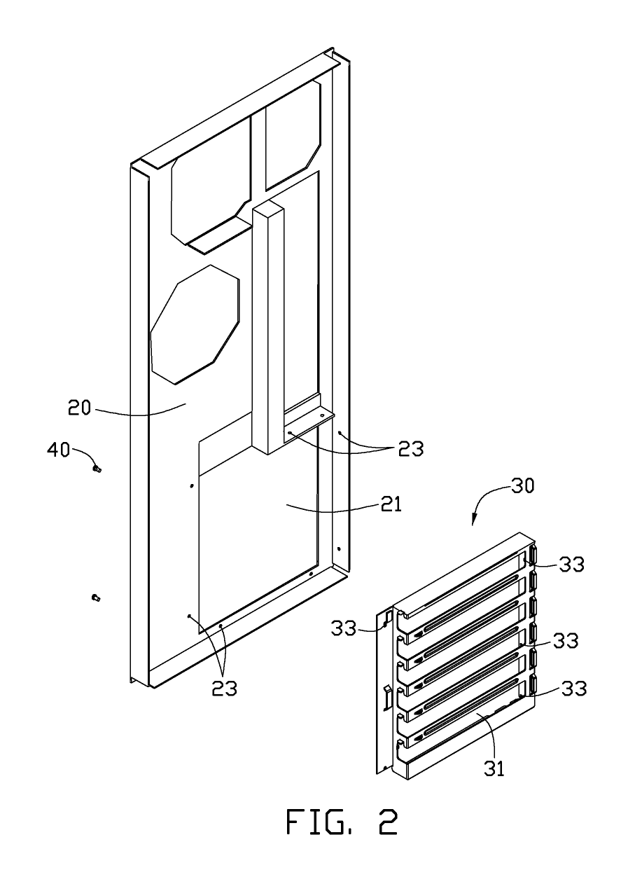

Referring to FIGS. 1 and 2, an embodiment of a computer case 10 includes a rear board 20, and a mounting bracket 30.

The rear board 20 defines a generally square-shaped opening 21. A plurality of first mounting holes 23 are defined in the rear board 20 around the opening 21.

The mounting bracket 30 is generally square-shaped. A plurality of parallel slots 31 are defined abreast of each other in the mounting bracket 30. A plurality of second mounting holes 33 are defined in the mounting bracket 30 around the plurality of slots 31, corresponding to the first mounting holes 23 of the rear board 20.

In assembly, a plurality of screws 40 engages in the plurality of first mounting holes 23 and the plurality of second mounting holes 33 to mount the mounting bracket 30 to the rear board 20, and therefore the mounting bracket 30 covers the opening 21.

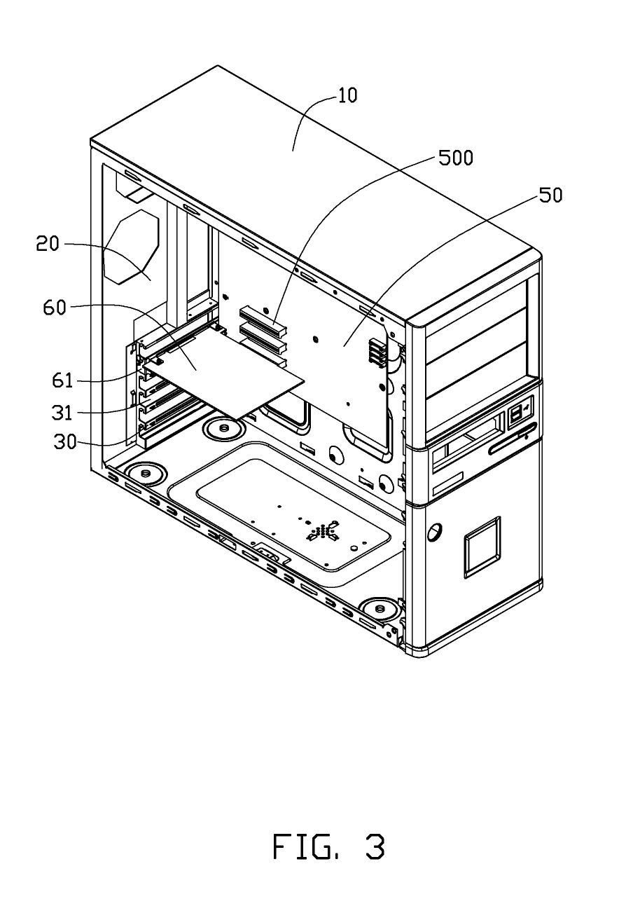

Referring to FIG. 3, a situation where a first motherboard 50 of a tower sever is mounted in the computer case 10 is shown. The first motherboard 50 is perpendicular to the rear board 20 and includes a plurality of peripheral component interconnect (PCI) sockets 500 perpendicular to the first motherboard 50 and the rear board 20. A PCI card 60 is directly coupled with the first motherboard 50 via engaging with one of the PCI sockets 500, and therefore the PCI card 60 is perpendicular to the first motherboard 50 and the rear board 20. The PCI card 60 includes a mounting portion 61 having a shape corresponding to one of the plurality of slots 31 of the mounting bracket 30, to be fixed to the mounting bracket 30 via known ways or fasteners and just to cover the corresponding slot 31. Therefore, when the mounting bracket 30 is pre-mounted to the rear board 20, the plurality of slots 31 of the mounting bracket 30 should be perpendicular to the first motherboard 50 as shown in FIG. 2, in order for the PCI card 60 to fit well therein. When the mounting portion 61 is fixed to the mounting bracket 30, a port (not shown) of the PCI card 60 is exposed through the corresponding slot 31 of the mounting bracket 30 to communicate with peripheral equipment (not shown).

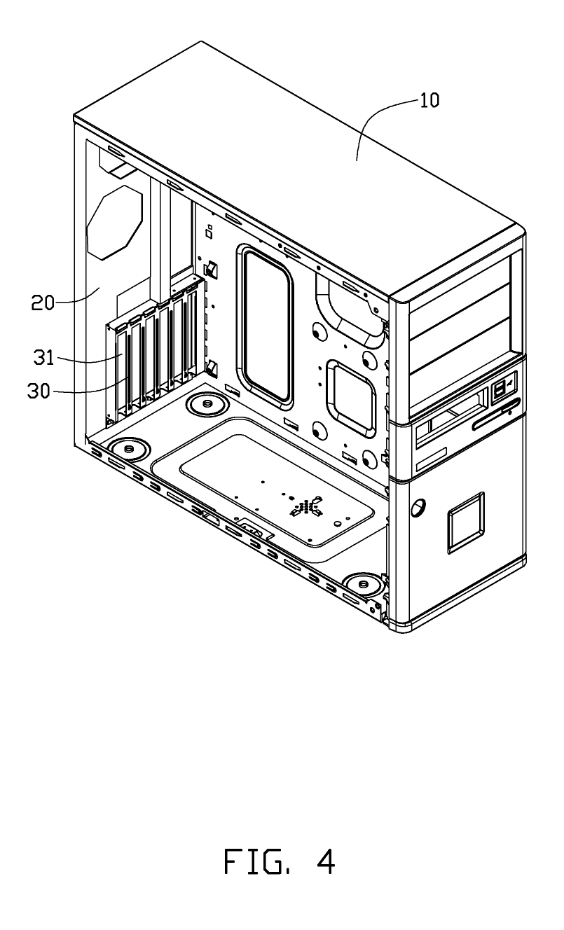

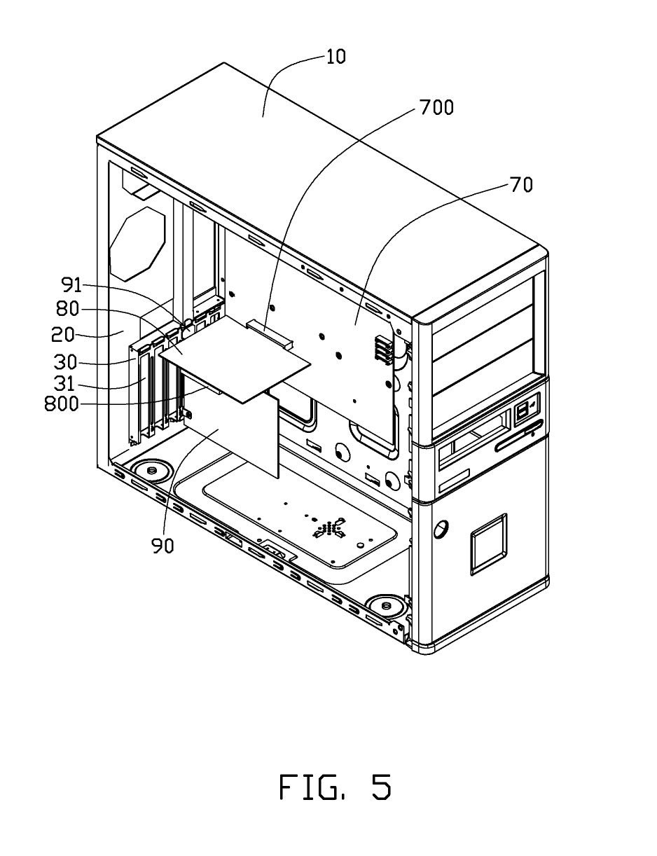

Referring to FIG. 5, a situation where a second motherboard 70 of a rack sever is mounted in the computer case 10 is shown. The second motherboard 70 includes a PCI socket 700. A riser card 80 is inserted in the PCI socket 700, and is perpendicular to the second motherboard 70. The riser card 80 includes a plurality of PCI sockets 800. A PCI card 90 is coupled with the riser card 80 via engaging with one of the PCI sockets 800 to indirectly connect with the second motherboard 70, and therefore the PCI card 90 is parallel with the second motherboard 70. The PCI card 90 includes a mounting portion 91 having a shape corresponding to one of the slots 31 of the mounting bracket 30. Therefore, when the mounting bracket 30 is pre-mounted to the rear board 20, the plurality of slots 31 of the mounting bracket 30 should be parallel with the second motherboard 70 as shown in FIG. 4, in order for the PCI card 90 to fit properly. When the mounting portion 91 is fixed to the mounting bracket 30, a port (not shown) of the PCI card 90 is exposed through the corresponding slot 31 of the mounting bracket 30 to communicate with peripheral equipment (not shown).

It is noted that the computer case 10 can be assembled in different manners as shown in FIGS. 1 and 4 to accommodate different motherboards, such as the first motherboard 50 and second motherboard 70. In detail, the mounting bracket 30 in FIG. 4 is rotated 90 degrees from its position in FIG. 1.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A computer case comprising:
a rear board defining an opening; and
a mounting bracket detachably mounted to the rear board, wherein when the mounting bracket is mounted to the rear board, the mounting bracket covers the opening, a plurality of parallel slots is defined abreast of each other in the mounting bracket;
wherein the mounting bracket is able to be mounted to the rear board in a first and a second states, the mounting bracket rotates 90 degrees in the second state relative to the first state.

2. The computer case of claim 1, wherein the rear board defines a plurality of first mounting holes around the opening, the mounting bracket defines a plurality of second mounting holes corresponding to the first mounting holes, and a plurality of screws engages in the plurality of first mounting holes and the plurality of second mounting holes to mount the mounting bracket to the rear board.

3. The computer case of claim 1, wherein the opening of the rear board is generally square-shaped.

4. A computer case comprising:
a rear board defining an opening; and
a mounting bracket detachably mounted to the rear board, wherein when the mounting bracket is mounted to the rear board, the mounting bracket covers the opening, a plurality of parallel slots is defined abreast of each other in the mounting bracket;
wherein the mounting bracket is able to be remounted to the rear board after the mounting bracket is detached from the rear board and rotated 90 degrees.

5. The computer case of claim 4, wherein the rear board defines a plurality of first mounting holes around the opening, the mounting bracket defines a plurality of second mounting holes corresponding to the first mounting holes, and a plurality of screws engages in the plurality of first mounting holes and the plurality of second mounting holes to mount the mounting bracket to the rear board.

6. The computer case of claim 5, wherein the opening of the rear board is generally square-shaped, and the mounting bracket is generally square-shaped.
